(19) United States
(12) Patent Application Publication
(10) Pub. No.: US 2024/0264635 A1
(43) Pub. Date: Aug. 8, 2024

(54) HANDLE FOR CLAIMPING SWITCH CONSOLE AND BEING ABLE TO PLACED ON SWITCH BASE

(71) Applicant: SHENZHEN SAITAKE ELECTRONIC CO., LTD, SHENZHEN (CN)

(72) Inventor: SIMING GUO, Shenzhen (CN)

(21) Appl. No.: 18/166,423

(22) Filed: Feb. 8, 2023

(51) Int. Cl. G06F 1/16; H01H 13/807; H01H 25/04; H05K 5/00; H05K 5/02

(52) U.S. Cl. CPC G06F 1/1656; H01H 13/807; H01H 25/041; H05K 5/0018; H05K 5/0221

(57) ABSTRACT

A handle for clamping Switch console and being able to be placed on Switch base, comprising a bottom shell, a middle shell connecting plate, a PCB board assembly, and left and right upper shells, the bottom shell is provided with staggered reinforcing ribs in the middle and holding parts on both sides. The holding part is provided with a cavity for placing the PCB board assembly and power cord, and the PCB board assembly is provided with charging and Bluetooth modules, and the power cord of the charging module extends to the outside of the bottom shell. The middle shell connecting plate is configured to be an L-shaped structure, which is divided into a handle button supporting plate and a beam plate, the width of the beam plate is less than half of the width of the holding part, the handle button supporting plate is arranged in the holding part.

### TECHNICAL FIELD

The present application relates to the field of game handles, and specifically refers to a handle for clamping a Switch console and being able to be placed on a Switch base.

### BACKGROUND

With the increasing popularity of portable switch game consoles, the console handles equipped with them cannot meet all the needs of players. For example, the existing console handles are all independently configured, with fixed button functions, etc., so that after the player finishes playing the game, if he places it at will, it will be easily lost. The lack of button functions when playing games results in a poor gaming experience. In addition, there are some handle brackets that are fully wrapped. When the handle bracket is set up with the Switch console for charging, assembling the handle bracket will result in the inability to snap into the charging device, and the rear support device that comes with the Switch console cannot be opened.

### SUMMARY

The present application aims to solve the above technical problems by providing a handle for clamping a Switch console and being able to be placed on a Switch base.

In order to solve the above technical problems, the technical solution provided by the present application is: a handle for clamping Switch console and being able to be placed on Switch base, comprising a bottom shell, a middle shell connecting plate, a PCB board assembly, and left and right upper shells, wherein the bottom shell is provided with staggered reinforcing ribs in the middle and holding parts on both sides, the holding part is provided with a cavity for placing the PCB board assembly and power cord, and the PCB board assembly is provided with charging and Bluetooth modules, and a power cord of the charging module extends to the outside of the bottom shell;
the middle shell connecting plate is configured to be an L-shaped structure, which is divided into a handle button supporting plate and a beam plate, wherein the width of the beam plate is less than half of the width of the holding part, and the handle button supporting plate is arranged in the holding part;
sliding ways are provided on the opposite sides of the holding parts, convex horizontal bars are provided on the middle shell connecting plate, and clamping edges are arranged above the left and right upper shells.

Further, two ends of the beam plate are provided with button fixing grooves, and the PCB board assembly is fixed on the clamping table arranged on the handle button supporting plate, and the PCB board assembly is provided with game buttons, including remote sensing, buttons and switches.

Further, the convex horizontal bars are arranged on an upper side of the beam plate.

Further, the clamping edges are arranged above a side of the left and right upper shells close to the middle shell connecting plate.

Further, the left and right upper shells are provided with through holes corresponding to the game buttons.

Further, the left and right upper shells are fastened above the bottom shell, the holding parts are provided with buckles, and the left and right upper shells are provided with clamping tables matched with the buckles.

Further, the middle shell connecting plate and the bottom shell are respectively provided with positioning holes and fixing holes that cooperate with each other.

Further, a game console is arranged between the beam plate and the two holding parts, a supporting plate is rotatably provided on back side of the game console, and the middle shell connecting plate does not affect the rotation of a supporting plate, a side of the game console is provided with a sliding chute matched the sliding way.

Further, after the handle composed of the bottom shell, the middle shell connecting plate, the PCB board assembly and the left and right upper shells and the game console are erected, the game console can be placed on a charging base for normal charging of the game console without disassembling the game console.

The advantage of the present application compared with the prior art is that the PCB board assembly in this technical solution is designed as a charging module and a Bluetooth module, which can be placed on the console base for charging after it is connected to the console without affecting the use of the hidden bracket of the console, and the console can be charged on the console base without disassembling the console.

### BRIEF DESCRIPTION OF DRAWINGS

FIG. 1 is a schematic structural diagram of a handle for clamping a Switch console and being able to be placed on a Switch base according to the present application.

FIG. 2 is an exploded diagram of a handle for clamping a Switch console and being able to be placed on a Switch base according to the present application.

FIG. 3 is a structural schematic diagram of the bottom shell and the middle shell connecting plate of the handle for clamping a Switch console and being able to be placed on a Switch base according to the present application.

FIG. 4 is a first structural schematic diagram of the use state of the handle for clamping a Switch console and being able to be placed on a Switch base according to the present application.

FIG. 5 is a second schematic structural diagram of the handle for clamping a Switch console and being able to be placed on a Switch base according to the present application.

FIG. 6 is a structural diagram of the charging base;

FIG. 7 is a side structural diagram of the charging base.

### REFERENCE SIGNS

1. Bottom shell; 101. Reinforcing rib; 102. Holding part; 103. Sliding way; 2. Middle shell connecting plate; 201. Handle button supporting plate; 202. Beam plate; 3. PCB board assembly; 4. Left and right upper shell; 5. Convex horizontal bar; 6. Clamping edge; 7. Button fixing groove; 8. Buckle; 9. Clamping table; 10. Positioning hole; 11. Fixing hole; 12. Game console; 13. Charging base.

### DETAILED DESCRIPTION

In order to make the technical problems, technical solutions and beneficial effects to be solved by the present application clearer, the present application will be further described in detail below in conjunction with the accompanying drawings and embodiments. It should be understood that the specific embodiments described here are only used to explain the present application, and are not intended to limit the present application.

In the description of the present application, it should be noted that unless otherwise specified and limited, the term “connection” should be understood in a broad sense, for example, it may be a fixed connection, a detachable connection, or an integral connection. Those of ordinary skill in the art can understand the specific meanings of the above terms in the present application in specific situations.

Working principle of the present application: A handle for clamping Switch console and being able to be placed on Switch base, comprising a bottom shell 1, a middle shell connecting plate 2, a PCB board assembly 3, and left and right upper shells 4, wherein two symmetrical holding parts 102 are arranged on the bottom shell, the holding part is provided with a cavity for placing the PCB board assembly 3 and power cord, the bottom shell 1 is provided with a plurality of reinforcing ribs 101 for strengthening the strength of the bottom shell 1. Since the thickness of the entire plate is relatively thin, if the design of the reinforcing ribs 101 is not added, the plate will be easily deformed and damaged.

The PCB board assembly 3 is provided with charging and Bluetooth modules, and a power cord of the charging module extends to the outside of the bottom shell, which can be placed on the console base for charging after it is connected to the console without affecting the use of the hidden bracket of the console.

The middle shell connecting plate 2 is configured to be an L-shaped structure, which is divided into a handle button supporting plate 201 and a beam plate 202, wherein two ends of the beam plate 202 are provided with button fixing grooves 7 for placing buttons. The length of the beam plate 202 is matched with the game console. The beam plate 202 is arranged on the top of the handle button supporting plate 201, not exceeding half of the handle button supporting plate 201. Such a design will not hinder the opening and closing of the supporting plate at the rear of the Switch game console, which is very convenient.

The PCB board assembly 3 is fixed on the upper end of the middle shell connecting plate 2, and the PCB board assembly 3 is provided with game buttons 301, including functional buttons such as remote sensing, buttons and switches, and the left and right upper shells 4 are provided with through holes corresponding to the game buttons 301, which are convenient to use.

The inner edges of the left and right upper shells 4 are provided with built-in clamping tables for fixing with the buckles 8 in the cavity of the holding part 102, so as to seal various components in the cavity.

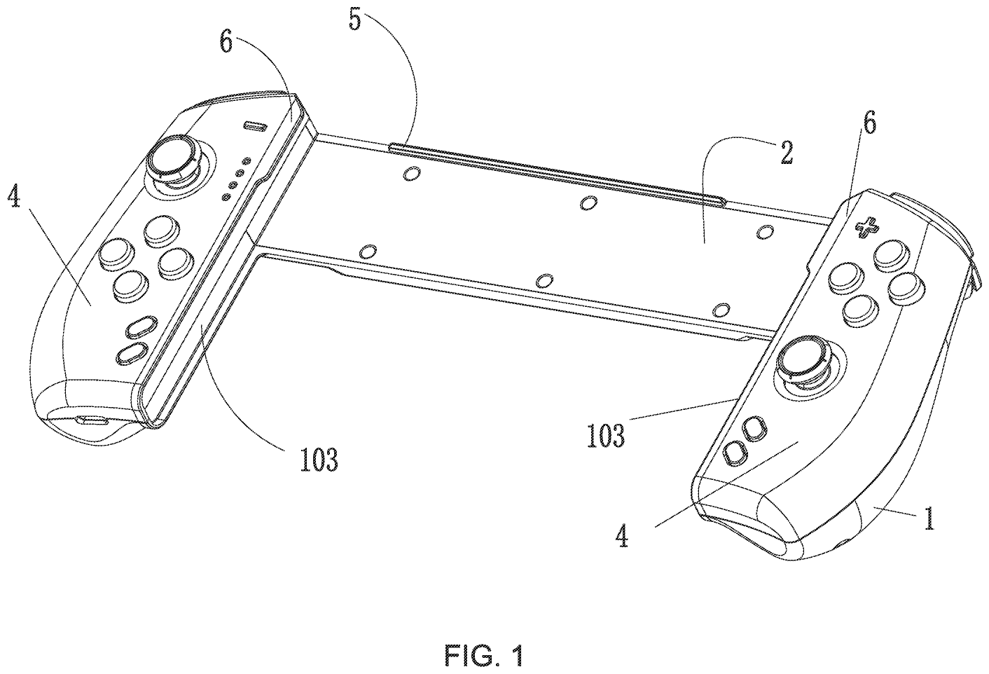

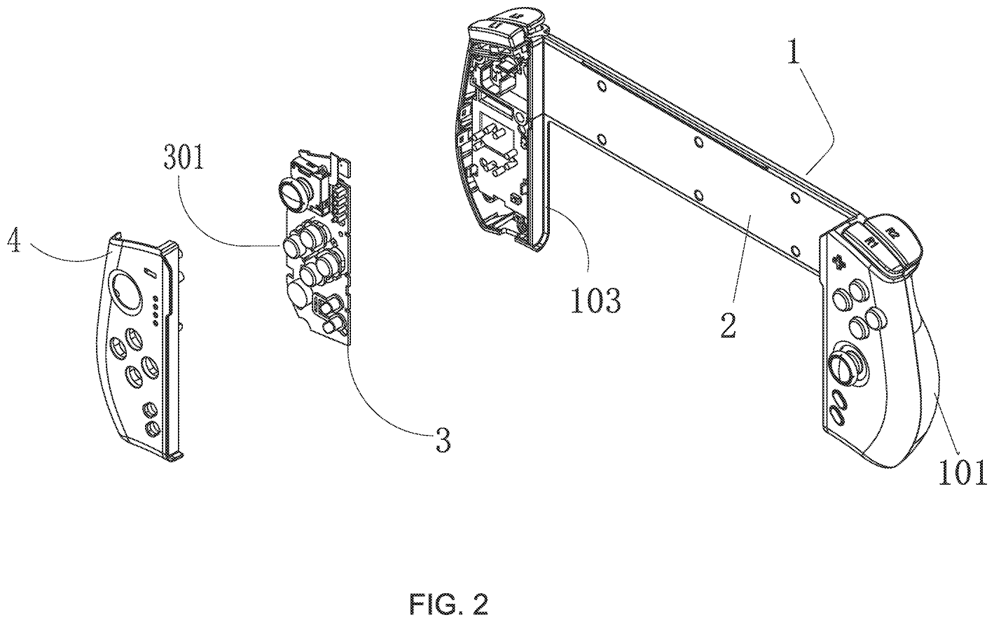

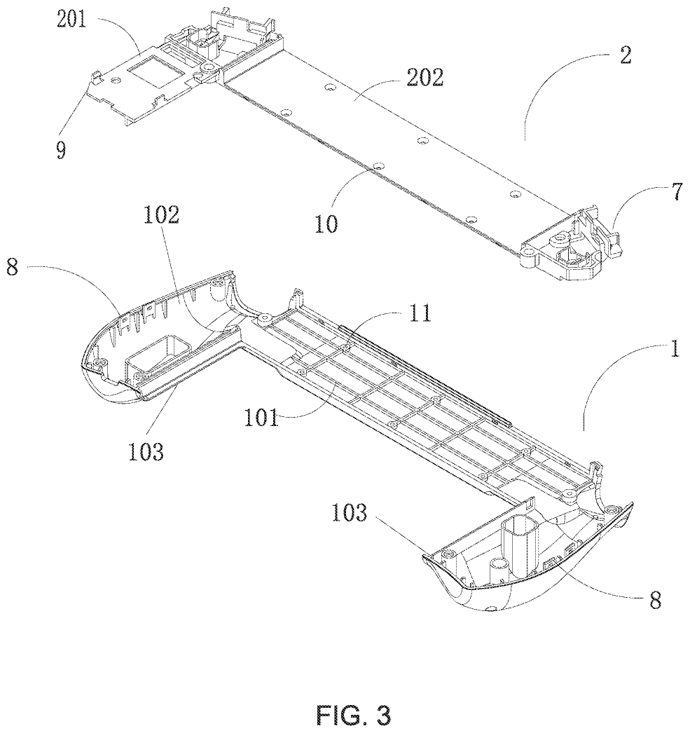

As shown in FIG. 1, in addition, the middle shell connecting plate 2 is also provided with a convex horizontal bar 5, and the convex horizontal bar 5 is arranged on an upper side of the beam plate 2, and the inner side of the bottom shell 1 is provided with sliding ways 103. The left and right upper shells 4 are provided with clamping edges 6, and on the same side. The clamping edges 6 are arranged above a side of the left and right upper shells 4 close to the middle shell connecting plate 2. As long as one clamping edge cooperates with the middle shell connecting plate, the game console can be fixed. The space formed by the clamping edge 6 and the sliding ways 103 can allow the game console to be slidably snapped into it. The distance between the clamping edge 6 and the sliding way 103 is the same as the thickness of the game console, so that when sliding in and clamping in, there will be no shaking. The convex horizontal bar 5 is used to fix the top of the game console, so that the game console will not fall out due to shaking, and at the same time it will not affect the artificial disassembly of the game console.

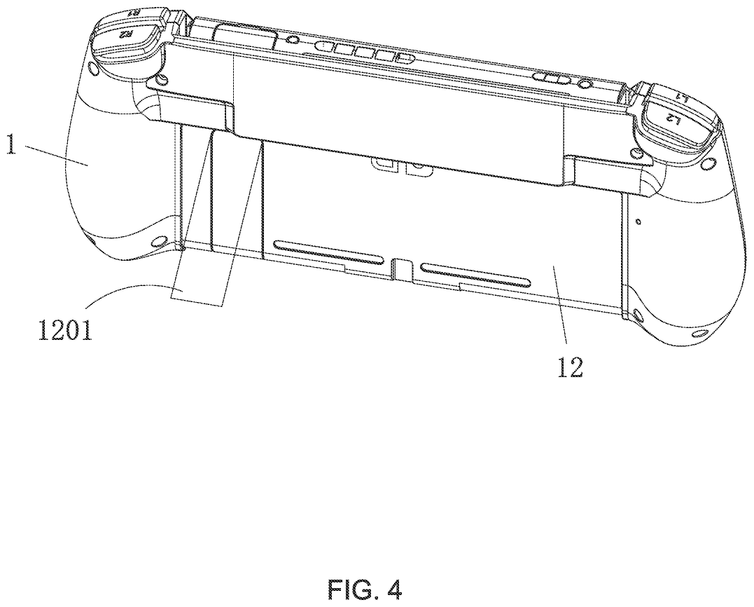

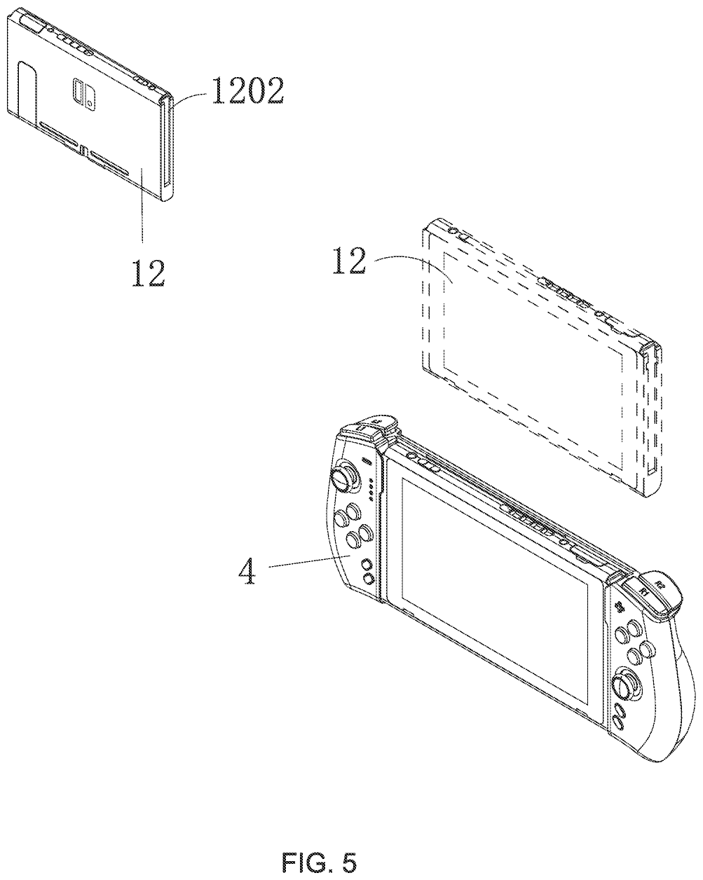

As shown in FIGS. 4-5, a game console 12 is provided between the beam plate 202 and the two holding parts 102. The back of the game console 12 is rotatably provided with a supporting plate 1201. The middle shell connection plate 2 does not affect the rotation of the supporting plate 1201. The side of the game console 12 is provided with a sliding chute 1202 matched with the sliding way 103. After the handle is inserted into the console, because the lower part is hollowed out, it will not increase the thickness of the game console. When the handle is put into the charging base for charging, it only needs to be erected, and there is no need to disassemble the handle, which is convenient and quick.

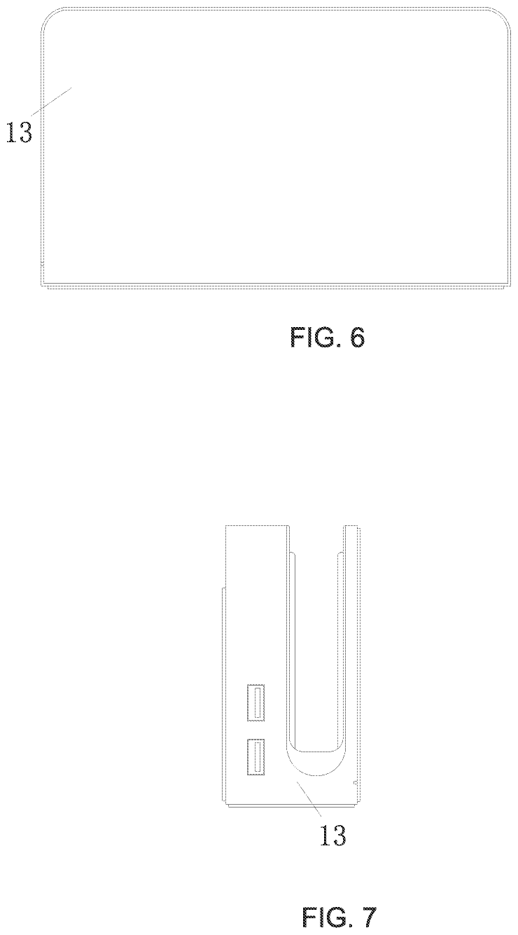

As shown in FIG. 6-7, when charging, connect the switch game console 12 to the handle and put it into the groove of the charging base 13 for charging.

The present application and its implementations are described above, and this description is not limiting. What is shown in the drawings is only one of the implementations of the present application, and the actual structure is not limited thereto. All in all, if a person skilled in the art is inspired by it, without departing from the purpose of the present application, without creatively designing a structural method and embodiment similar to the technical solution, it shall fall within the protection scope of the present application.

What is claimed is:

1. A handle for clamping Switch console and being able to be placed on Switch base, comprising a bottom shell (1), a middle shell connecting plate (2), a PCB board assembly (3), and left and right upper shells (4), wherein the bottom shell (1) is provided with staggered reinforcing ribs (101) in the middle and holding parts (102) on both sides, the holding part (102) is provided with a cavity for placing the PCB board assembly (3) and power cord, and the PCB board assembly (3) is provided with charging and Bluetooth modules, and a power cord of the charging module extends to the outside of the bottom shell;
the middle shell connecting plate (2) is configured to be an L-shaped structure, which is divided into a handle button supporting plate (201) and a beam plate (202), wherein the width of the beam plate (202) is less than half of the width of the holding part (102), and the handle button supporting plate (201) is arranged in the holding part (102);
sliding ways (103) are provided on the opposite sides of the holding parts (102), convex horizontal bars (5) are provided on the middle shell connecting plate (2), and clamping edges (6) are arranged above the left and right upper shells (4).

2. A handle for clamping Switch console and being able to be placed on Switch base according to claim 1, wherein two ends of the beam plate (202) are provided with button fixing grooves (7), and the PCB board assembly (3) is fixed on the clamping table (9) arranged on the handle button supporting plate (201), and the PCB board assembly (3) is provided with game buttons (301), including remote sensing, buttons and switches.

3. A handle for clamping Switch console and being able to be placed on Switch base according to claim 1, wherein the convex horizontal bar (5) is arranged on an upper side of the beam plate (202).

4. A handle for clamping Switch console and being able to be placed on Switch base according to claim 1, wherein clamping edges (6) are arranged above a side of the left and right upper shells (4) close to the middle shell connecting plate (2).

5. A handle for clamping Switch console and being able to be placed on Switch base according to claim 2, wherein the left and right upper shells (4) are provided with through holes corresponding to the game buttons (301).

6. A handle for clamping Switch console and being able to be placed on Switch base according to claim 1, wherein the left and right upper shells (4) are fastened above the bottom shell (1), the holding parts (102) are provided with buckles (8), and the left and right upper shells (4) are provided with clamping tables matched with the buckles (8).

7. A handle for clamping Switch console and being able to be placed on Switch base according to claim 1, wherein the middle shell connecting plate (2) and the bottom shell (1) are respectively provided with positioning holes (10) and fixing holes (11) that cooperate with each other.

8. A handle for clamping Switch console and being able to be placed on Switch base according to claim 1, wherein a game console (12) is arranged between the beam plate (202) and the two holding parts (102), a supporting plate (1201) is rotatably provided on back side of the game console (12), and the middle shell connecting plate does not affect the rotation of a supporting plate, a side of the game console (12) is provided with a sliding chute (1202) matched the sliding way (103).

9. A handle for clamping Switch console and being able to be placed on Switch base according to claim 8, wherein after the handle composed of the bottom shell (1), the middle shell connecting plate (2), the PCB board assembly (3) and the left and right upper shells (4) and the game console (12) are erected, the game console (12) can be placed on a charging base (13) for normal charging of the game console (12) without disassembling the game console (12).
